(19) United States
(12) Patent Application Publication
(10) Pub. No.: US 2011/0159680 A1
(43) Pub. Date: Jun. 30, 2011

(54) METHOD OF FORMING A DIELECTRIC LAYER AND METHOD OF MANUFACTURING A SEMICONDUCTOR DEVICE USING THE SAME

(75) Inventors: Dong-Chul YOO, Seongnam-si (KR); Byong-Ju KIM, Suwon-si (KR); Han-Mei CHOI, Seoul (KR); Ki-Hyun HWANG, Seongnam-si (KR)

(73) Assignee: Samsung Electronics Co., Ltd.

(21) Appl. No.: 12/975,071

(22) Filed: Dec. 21, 2010

(30) Foreign Application Priority Data
Dec. 31, 2009 (KR) 10-2009-0135106

(51) Int. Cl. H01L 21/28; B05D 5/12

(52) U.S. Cl. 438/591; 427/126.4; 427/79; 257/E21.21

(57) ABSTRACT

In a method of forming an aluminum oxide layer, an aluminum source gas and a dilution gas can be supplied into a chamber through a common gas supply nozzle so that the aluminum source gas may be adsorbed on a substrate in the chamber. A first purge gas can be supplied into the chamber to purge the physically adsorbed aluminum source gas from the substrate. An oxygen source gas may be supplied into the chamber to form an aluminum oxide layer on the substrate. A second purge gas may be supplied into the chamber to purge a reaction residue and the physically adsorbed remaining gas from the substrate. The operations can be performed repeatedly to form an aluminum oxide layer having a desired thickness.

### PRIORITY STATEMENT

This application claims priority under 35 U.S.C. §119 to Korean Patent Application No. 2009-135106, filed on Dec. 31, 2009 in the Korean Intellectual Property Office (KIPO), the entire contents of which are herein incorporated by reference.

### BACKGROUND

1. Field

Example embodiments relate to a method of forming a dielectric layer and a method of manufacturing a semiconductor device using the same. More particularly, example embodiments relate to a method of forming a dielectric layer of aluminum oxide and a method of manufacturing a semiconductor device using the same

2. Description of the Related Art

Generally, a semiconductor device may include a dielectric layer having a high dielectric constant. For example, the dielectric layer may be included in a capacitor, a blocking dielectric layer of a flash memory device, a gate oxide layer, etc. Recently, an aluminum oxide layer may be used for the dielectric layer having a high dielectric constant.

The aluminum oxide layer may have a high density and low impurity content. In addition, it may be preferable that shrinking of the aluminum oxide layer hardly occurs under a high temperature and the aluminum oxide layer has a reproducible etch rate. Further, the aluminum oxide layer may have an excellent trapping, current leakage and bad gap properties.

### SUMMARY

According to example embodiments, in a method of forming an aluminum oxide layer, an aluminum source gas and a dilution gas are supplied into a chamber through a common gas supply nozzle so that the aluminum source gas is adsorbed on a substrate in the chamber. A first purge gas is supplied into the chamber to purge the physically adsorbed aluminum source gas from the substrate. An oxygen source gas is supplied into the chamber to form an aluminum oxide layer on the substrate. A second purge gas is supplied into the chamber to purge a reaction residue and the physically adsorbed remaining gas from the substrate. The steps are performed repeatedly to form an aluminum oxide layer having a desired thickness.

In example embodiments, the substrate may be heated to a temperature of about 450° C. to 700° C. in the chamber.

In example embodiments, the flow rate of the dilution gas may be controlled such that the aluminum source gas is prevented from being decomposed in the gas supply nozzle. The flow rate ratio of the aluminum source gas and the dilution gas may be in a range of about 1:5 to about 1:80.

In example embodiments, the aluminum source gas may include trimethyl aluminium (Al(CH3)3), triethyl aluminium (Al(C2H6)3), triisobutyl aluminium (Al[(C2H3(CH3)2]3), diethyl aluminium chloride (AlCl(C2H6)3), etc. These may be used alone or in a mixture thereof.

In example embodiments, the dilution gas may include nitrogen, argon, helium, etc. These may be used alone or in a mixture thereof.

In example embodiments, the oxygen source gas may include ozone or vapor.

In example embodiments, the oxygen source gas may include an ozone gas and the ozone gas may be supplied with a concentration of about 350 g/cm³ and at a flow rate of about 10 slm.

In example embodiments, the ozone gas may be generated from a plurality of ozone generators and the ozone gas may be supplied into chamber through a common nozzle.

In example embodiments, the aluminum source gas and the dilution gas may converge into a common gas supply tube from the respective gas supply tube such that the aluminum source gas is diluted with the dilution gas and the aluminum source gas diluted with the dilution gas may be supplied into the chamber through the common gas supply nozzle.

In example embodiments, the method may further include thermally treating the aluminum oxide layer.

According to example embodiments, in a method of manufacturing a flash memory device, a tunnel oxide layer and a charge trapping layer pattern are formed on a substrate. The substrate including the charge trapping layer is loaded into a chamber. An aluminum source gas and a dilution gas are supplied into the chamber through a common gas supply nozzle so that the aluminum source gas is adsorbed on the substrate in the chamber. A first purge gas is supplied into the chamber to purge the physically adsorbed aluminum source gas from the substrate. An oxygen source gas is supplied into the chamber to form an aluminum oxide layer on the substrate. A second purge gas is supplied into the chamber to purge a reaction residue and the physically adsorbed remaining gas from the substrate. A control gate electrode is formed on the aluminum oxide layer.

In example embodiments, the substrate may be heated to a temperature of about 450° C. to 700° C. when the aluminum oxide layer is formed in the chamber.

In example embodiments, the flow rate ratio of the aluminum source gas and the dilution gas may be in a range of about 1:5 to about 1:80.

In example embodiments, the charge trapping layer may include polysilicon or silicon nitride.

In example embodiments, the control gate electrode may include a metal pattern that contacts the aluminum oxide layer.

According to example embodiments, in a method of manufacturing a capacitor, a lower electrode is formed on a substrate. The substrate including the lower electrode is loaded into a chamber. An aluminum source gas and a dilution gas are supplied into the chamber through a common gas supply nozzle so that the aluminum source gas is adsorbed on the substrate in the chamber. A first purge gas is supplied into the chamber to purge the physically adsorbed aluminum source gas from the substrate. An oxygen source gas is supplied into the chamber to form an aluminum oxide layer on the substrate. A second purge gas is supplied into the chamber to purge a reaction residue and the physically adsorbed remaining gas from the substrate. An upper electrode is formed on the aluminum oxide layer.

In example embodiments, the substrate may be heated to a temperature of about 450° C. to 700° C. when the aluminum oxide layer is formed in the chamber.

In example embodiments, the flow rate ratio of the aluminum source gas and the dilution gas may be in a range of about 1:5 to about 1:80.

In example embodiments, the upper electrode may include metal and polysilicon.

According to example embodiments, an aluminum oxide layer formed by the above methods may have low impurity content and a high density. In addition, the aluminum oxide layer may have excellent shrinkage and etching properties during manufacturing processes. Further, a trap generation of electron or hole in the aluminum oxide layer may be reduced, to thereby provide excellent current leakage and band gap properties. Accordingly, the aluminum oxide layer according to example embodiments may be used for a capacitor of DRAM and an interpoly dielectric (IPD) or a blocking dielectric layer of a flash memory device.

### BRIEF DESCRIPTION OF THE DRAWINGS

Example embodiments will be more clearly understood from the following detailed description taken in conjunction with the accompanying drawings. FIGS. 1 to 33 represent non-limiting, example embodiments as described herein.

FIG. 1 is a view illustrating a deposition reactor for forming a dielectric layer in accordance with example embodiments.

FIG. 2 is a graph illustrating a method of forming a dielectric layer in accordance with example embodiments.

FIG. 3 is a plan view illustrating a flash memory device in accordance with a first example embodiment.

FIG. 4 is a cross-sectional view illustrating the flash memory device in FIG. 3.

FIGS. 5 to 8 are cross-sectional views illustrating a method of manufacturing the flash memory device in FIGS. 3 and 4.

FIG. 9 is a cross-sectional view illustrating a flash memory device in accordance with a second example embodiment.

FIG. 10A is a perspective view illustrating a vertical-type NAND flash memory device in accordance with a third example embodiment.

FIG. 10B is a cross-sectional view illustrating the vertical-type NAND flash memory device of FIG. 10A.

FIGS. 11 to 19 are cross-sectional views illustrating a method of manufacturing the vertical-type NAND flash memory device in FIGS. 10A and 10B.

FIG. 20 is a cross-sectional view illustrating a capacitor in accordance with a fourth example embodiment.

FIG. 21 is a cross-sectional view illustrating a DRAM device in accordance with a fifth example embodiment.

FIGS. 22 to 24 are cross-sectional views illustrating a method of manufacturing a DRAM device.

FIG. 25 illustrates a graph showing densities of aluminum oxide layers according to Example and Comparative Example.

FIG. 26 illustrates a graph showing etched thicknesses of aluminum oxide layers versus an etching time according to Example and Comparative Example.

FIG. 27 illustrates a graph showing thicknesses of aluminum oxide layers before/after a crystallization process according to Example and Comparative Example.

FIG. 28 illustrates a graph showing current densities of aluminum oxide layers versus an electric field according to Example and Comparative Example.

FIG. 29 illustrates a graph showing hydrogen contents in aluminum oxide layers according to Example and Comparative Example.

FIG. 30 illustrates another exemplary embodiment.

FIG. 31 illustrates yet another exemplary embodiment.

FIG. 32 illustrates a further exemplary embodiment.

FIG. 33 illustrates a still further exemplary embodiment.

### DETAILED DESCRIPTION OF EXAMPLE EMBODIMENTS

Various example embodiments will be described more fully hereinafter with reference to the accompanying drawings, in which example embodiments are shown. Example embodiments may, however, be embodied in many different forms and should not be construed as limited to example embodiments set forth herein. Rather, these example embodiments are provided so that this disclosure will be thorough and complete, and will fully convey the scope of example embodiments to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

Deposition Apparatus for Forming a Dielectric Layer

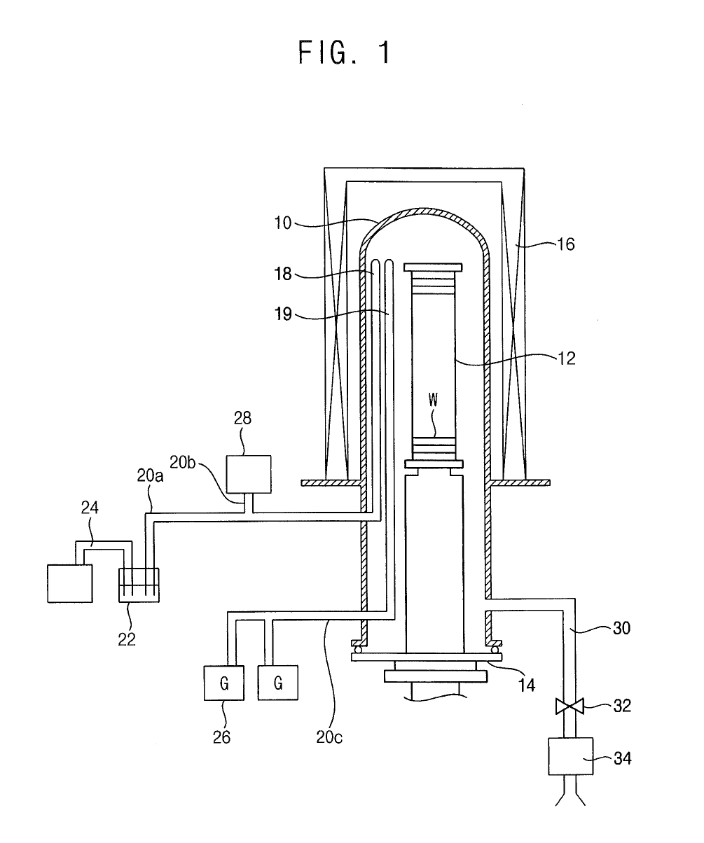

FIG. 1 is a view illustrating a deposition reactor for forming a dielectric layer in accordance with example embodiments.

Referring to FIG. 1, a reaction chamber 10 may be provided to perform a deposition process. The reaction chamber 10 may have a space for receiving a plurality of wafers (W). A lower end of the reaction chamber 10 may be hermetically sealed by a manifold and a sealing cap.

A boat 12 may be inserted into the reaction chamber 10 through the sealing cap 14 to load the wafer (W). The wafers (W) may be disposed in the boat 12 to be batch processed.

A heater 16 may heat the wafers (W) within the reaction chamber 10. The heater 16 may be provided outside the reaction chamber 10.

At least one gas supply nozzle 18 may be provided in the reaction chamber 10. A plurality of gas supply holes may be formed in the gas supply nozzle 18 to supply gases into the reaction chamber 10 through the gas supply holes.

A gas supply tube may be connected to the gas supply nozzle 18 to provide the gases from the outside for the reaction chamber 10. A plurality of the gas supply tubes may be provided corresponding to various types of the gases. The gas supply tube may penetrate a lower portion of the manifold to be connected to the gas supply nozzle 18.

For example, an aluminum source gas may flow through a first gas supply tube 20a. A dilution gas for diluting the aluminum source gas may flow through a second gas supply tube 20b. An end portion of the second gas supply tube 20b may be connected to the first gas supply tube 20a. The second gas supply tube 20b may branch off from the first gas supply tube 20a.

An oxygen gas may flow through a third gas supply tube 20c. A carrier gas may flow through a carrier gas supply tube 24. The carrier gas may be provided to bubble and vaporize a liquid form of the aluminum source.

A first mass flow controller (not illustrated) and a first valve (not illustrated) for controlling a flow rate may be provided in the first gas supply tube 20a.

The first gas supply tube 20a may be connected to an aluminum source container 22.

The carrier gas supply tube 24 may be connected to the aluminum source container 22. The aluminum source of the aluminum source container 22 may be in a liquid state at a room temperature. The carrier gas from the carrier gas supply tube 24 may be supplied into the aluminum source container 22 to vaporize the aluminum source.

The second gas supply tube 20b may be connected to a dilution gas supply container 28. Accordingly, the dilution gas from the dilution gas supply container 28 may flow through the first gas supply tube 20a. Thus, the aluminum source gas may be diluted by the dilution gas, and then, may be supplied into the reaction chamber 10 from the first gas supply tube 20a.

A second mass flow controller (not illustrated) and a second valve (not illustrated) for controlling a flow rate may be provided in the third gas supply tube 20c.

The third gas supply tube 20c may be connected to at least one oxygen source gas generator. The oxygen source gas generator may be an ozone generator. As illustrated in the figure, the third gas supply tube 20c may be connected to a plurality of the ozone generators 26 to provide high density ozone for the reaction chamber 10. Alternatively, the third gas supply tube 20c may be connected to one ozone generator 26.

A gas exhaust tube 30 may be connected to the reaction chamber 10 and may be connected to a vacuum pump 34 via a valve 32.

Deposition Method of Forming a Dielectric Layer

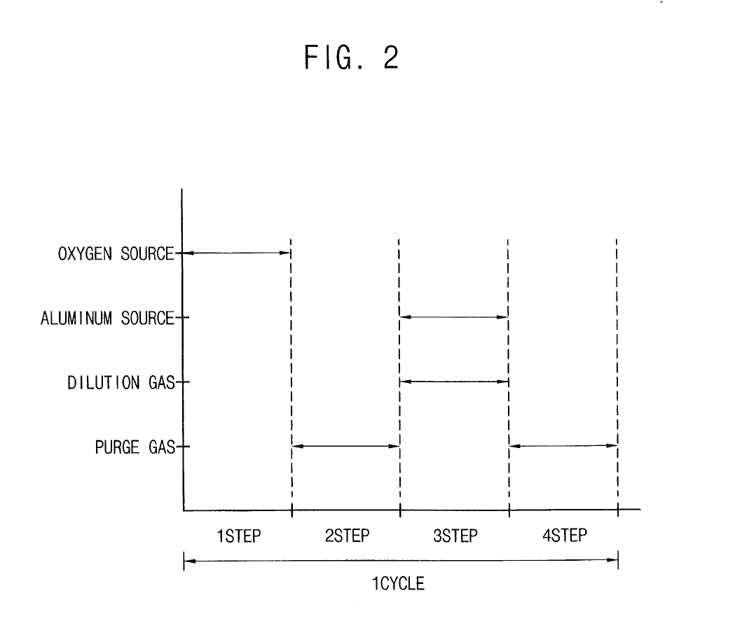

FIG. 2 is a graph illustrating a method of forming a dielectric layer in accordance with example embodiments.

Hereinafter, a method of forming a dielectric layer using the deposition reactor of FIG. 1 will be explained with reference to FIG. 2.

Referring to FIG. 2, a plurality of wafers (W) may be loaded in the reaction chamber 10 of the batch-type deposition reactor. The wafers (W) may be spaced apart from one another in the boat 12.

The wafers (W) may be heated to a temperature of about 450° C. to 700° C. in the reaction chamber 10.

When a process of forming an aluminum oxide layer is performed under about 450° C., impurities in the aluminum oxide layer may be increased and the layer density may be decreased. Accordingly, the layer may excessively shrink during a heating process. For example, when a wet etch process is performed, the etching rate and the etching distribution of the layer may be increased. Further, a trapping property of the aluminum oxide layer may be deteriorated, to thereby increase a current leakage. On the other hand, when a process of forming an aluminum oxide layer is performed above about 700° C., the aluminum source gas may be decomposed.

In a first step, the carrier gas may be supplied into the aluminum source container 22 including an aluminum source to vaporize the aluminum source. The vaporized aluminum source may be supplied together with the carrier gas into the reaction chamber 10. The aluminum source gas may flow though the first gas supply tube 20a into the reaction chamber.

Examples of the aluminum source may be trimethyl aluminium (Al(CH₃)₃), triethyl aluminium (Al(C₂H₆)₃), triisobutyl aluminium (Al[(C₂H₃(CH₃)₂]₃), diethyl aluminium chloride (AlCl(C₂H₆)₃), etc. These may be used alone or in a mixture thereof. In this embodiment, trimethyl aluminium (TMA) may be used as the aluminum source gas.

A dilution gas may be supplied together with the aluminum source gas into the reaction chamber 10. The dilution gas may include an inert gas. For example, the dilution gas may include nitrogen, argon, helium, etc. These may be used alone or in a mixture thereof.

The dilution gas may flow the first gas supply tube 20a from the second gas supply tube 20b to dilute the aluminum source gas. The diluted aluminum source gas may be supplied into the reaction chamber 10. The aluminum source gas and the dilution gas may be supplied into the reaction chamber 10 through a common gas supply tube, that is, the first gas supply tube 20a. Accordingly, the aluminum source gas and the dilution gas may be supplied into the reaction chamber 10 through a common gas supply nozzle, that is, the gas supply nozzle 18.

However, when only the aluminum source gas may be supplied into the reaction chamber through the first gas supply tube 20a and the dilution gas may be supplied into the reaction chamber through another gas supply tube by a conventional method, the aluminum source gas may be easily decomposed under a deposition temperature of about 450° C. to 700° C. Accordingly, the decomposed aluminum may be adsorbed on the first gas supply tube 10a, the reaction chamber 10 and the boat 12, to thereby pollute the deposition apparatus. Further, since the aluminum source gas is decomposed in the reaction chamber 10, the thickness distribution of layers to be formed on each of the wafers (W) may be increased.

In this embodiment, the aluminum source gas and the dilution gas may be supplied into the reaction chamber through the same gas supply tube. Accordingly, the aluminum source gas may be prevented from being decomposed under a temperature of about 450° C. to 700° C.

For example, the aluminum source gas having a first flow rate and the dilution gas having a second flow rate may be supplied into the reaction chamber 10. The flow rate ratio of the second flow rate relative to the first flow rate may be above about 5. When the aluminum source gas is supplied together with the dilution gas into the reaction chamber, the speed of the aluminum source gas may be increased and the concentration of the aluminum source gas of the whole inflow gas may be relatively decreased. Accordingly, the aluminum source gas may be prevented from decomposed under a temperature of about 450° C. to 700° C.

As the second flow rate of the dilution gas is more increased, the decomposition of the aluminum source gas may be more decreased. However, when the flow rate ratio of the second flow rate relative to the first flow rate is above about 80, the concentration of the aluminum source gas may be relatively decreased so that the deposition rate of the aluminum oxide layer is relatively decreased. Accordingly, the flow rate of the second flow rate relative to the first flow rate may be in a range of about 5 to about 80.

In a second step, a purge gas may be supplied into the reaction chamber to purge the aluminum source gas from the reaction chamber. For example, the inflow of the aluminum source gas may be stopped, and then, the purge gas may be supplied into the reaction chamber. The purge gas may include an inert gas.

In a third step, the oxygen source gas may be supplied into the wafers in the reaction chamber 10. The oxygen gas may include ozone, vapor, etc. In this embodiment, an ozone gas may be used as the oxygen source gas. The ozone gas may be supplied into the reaction chamber from the third gas supply tube 20c. Accordingly, in this embodiment, the ozone gas may be supplied into the reaction chamber 10 through a common nozzle 19 from a plurality of the ozone generators.

The supplied ozone gas may have a concentration of about 350 g/cm³ and may have a flow rate of more than about 10 slm (standard liter per minute). In this embodiment, the flow rate and the concentration of the ozone gas may be controlled such that oxygen completely fills vacancies of the aluminum oxide layer where there is a lack of oxide. Accordingly, as illustrated in FIG. 1, a plurality of the ozone generators may be provided in the deposition apparatus.

The ozone gas may react with the aluminum source gas that is adsorbed on the wafer, to form an aluminum oxide (Al₂O₃) layer on the wafer.

As mentioned above, the aluminum oxide layer may be formed under a temperature of about 450° C. to 700° C. As the aluminum oxide layer is formed under a high temperature, the aluminum oxide layer may have a high density and low impurity content, to thereby improve current leakage characteristics.

In a fourth step, a purge gas may be supplied into the reaction chamber to purge the oxygen source gas from the reaction chamber. For example, the inflow of the ozone source gas may be stopped, and then, the purge gas may be supplied into the reaction chamber. The purge gas may include an inert gas.

The first to fourth steps may constitute one cycle and the cycle may be performed repeatedly to form an aluminum oxide layer having a desired thickness.

The In-Wafer thickness distribution of the aluminum oxide layer formed by the processes may be below about 1%. The thickness (wafer to wafer thickness) distribution between the aluminum oxide layers formed on the wafers may be below about 1%. Accordingly, the thickness distribution of the aluminum oxide layer across the wafer and the thickness distribution between the aluminum oxide layers on the wafers may be decreased, to thereby obtain an aluminum oxide layer having a uniform thickness.

Because the aluminum oxide layer formed by the method illustrated with reference to FIGS. 1 and 2 has a high density and low impurity content, the aluminum oxide layer may have excellent shrinkage and etching properties during manufacturing processes. Further, the aluminum oxide layer may be low in hydrogen content, to thereby provide excellent trapping, current leakage and bad gap properties.

### EMBODIMENT 1

Hereinafter, a flash memory device including the aluminum oxide layer that is illustrated with reference to FIGS. 1 and 2 and a method of manufacturing the flash memory device will be explained in detail.

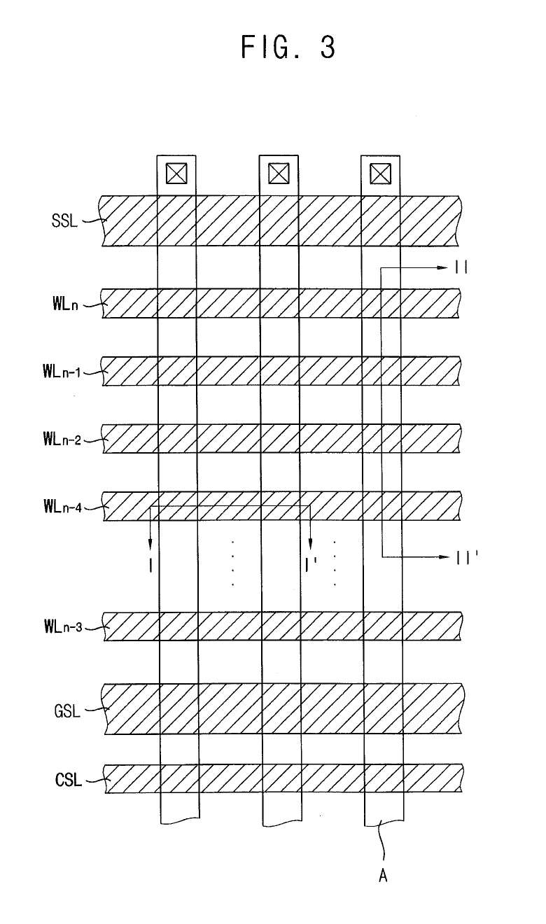

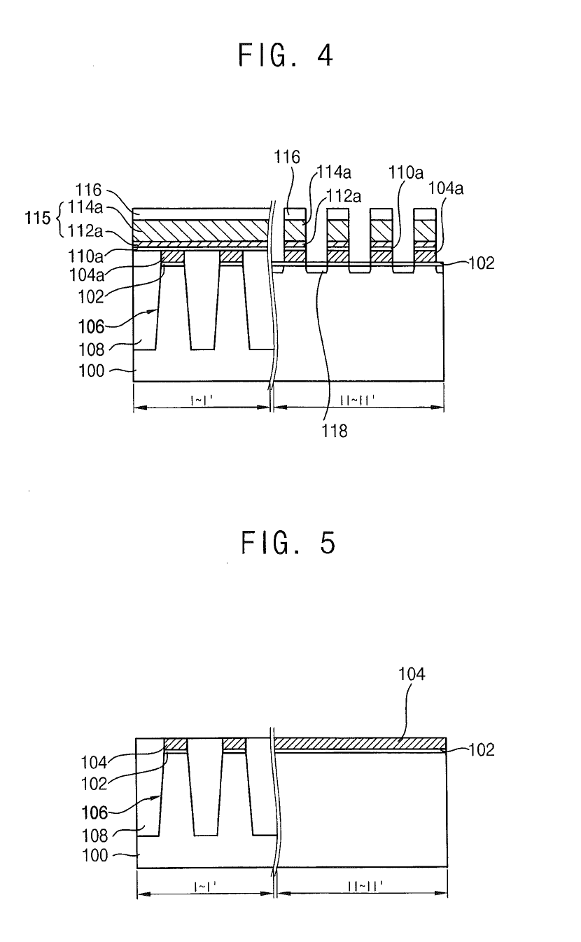

FIG. 3 is a plan view illustrating a flash memory device in accordance with a first example embodiment. FIG. 4 is a cross-sectional view illustrating the flash memory device in FIG. 3. FIG. 4 is a cross-sectional view taken along the line I-I′ and the line II-II′ in FIG. 3.

Referring to FIGS. 3 and 4, a substrate 100 having an isolation layer pattern 108 may be provided. The isolation layer pattern may define an active region in the substrate 100. The active region may have a linear shape extending a first direction.

A tunnel oxide layer 102 and a floating gate pattern 104a may be provided on the substrate 100. The tunnel oxide layer 102 may include silicon oxide. The floating gate pattern 104a may include polysilicon doped with impurities.

A dielectric layer pattern 110a may be provided on the floating gate pattern 104a and the isolation layer pattern 108. The dielectric layer pattern 110a may have a linear shape extending in a direction perpendicular to the isolation layer pattern 108. The dielectric layer pattern 110a may include aluminum oxide. The aluminum oxide may be formed by the method illustrated with reference to FIGS. 1 and 2. Accordingly, the aluminum oxide may have a high density due to the reduced oxide vacancies and may have an excellent trapping property due to the low impurity content. Thus, the flash memory device may include the dielectric layer pattern having a high density and low impurity content, to thereby decrease a current leakage and improve reliability thereof.

A control gate pattern 115 may be provided on the dielectric layer pattern 110a. The control gate pattern 115 may have a stacked structure of a metal layer pattern 112a and a polysilicon layer pattern 114a. The metal layer pattern 112a may include titanium, titanium nitride, tantalum, tantalum nitride, etc. These may be used alone or in a combination thereof. The control gate pattern 115 may be used as a word line. The control gate pattern 115 may have a linear shape extending in a second direction perpendicular to the first direction.

A hard mask pattern 116 may be provided on the control gate pattern 115.

An impurity region 118 may be provided under a surface of the substrate 100 in both sides of a gate structure including the tunnel oxide layer 102, the floating gate pattern 104a, the dielectric layer pattern 110a, the control gate pattern 115 and the hard mask pattern 116.

As illustrated in FIG. 3, selection transistors may be provided to select a sell string. A gate electrode of the selection transistor may be used as a source selection line (SSL) or a ground selection line (GSL). A bit line and a common source line (CSL) may be provided on the substrate 100.

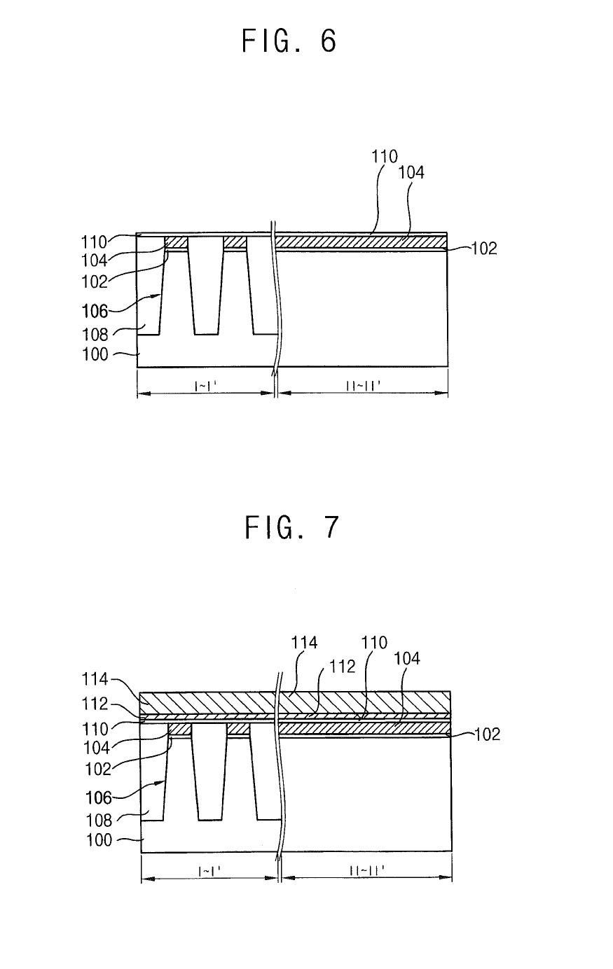

FIGS. 5 to 8 are cross-sectional views illustrating a method of manufacturing the flash memory device in FIGS. 3 and 4. FIGS. 5 to 8 illustrate cross sections taken along the line I-I′ and the line II-II′.

Referring to FIG. 5, a tunnel oxide layer 102 and a floating gate layer (not illustrated) may be sequentially formed on a substrate 100. The substrate 100 may be a semiconductor substrate including silicon or germanium. A surface of the substrate 100 may be thermally oxidized by a thermal oxidation process to form the tunnel oxide layer 102. The floating gate layer may be formed using a polysilicon layer.

A first hard mask pattern (not illustrated) may be formed on the floating gate layer. The floating gate layer, the tunnel oxide layer 102 and the substrate 100 may be etched using the first hard mask pattern as an etching mask, to form a preliminary gate pattern 104. A trench 106 may be formed in an isolation region of the substrate 100.

An insulation layer may be formed to fill the trench 106 and the preliminary floating gate pattern 104, and then, may be planarized to form an isolation layer pattern 108. Then, the first hard mask pattern may be removed from the substrate 100.

Referring to FIG. 6, an aluminum oxide layer 110 for a blocking dielectric layer may be formed on the preliminary gate pattern 104 and the isolation layer pattern 108.

The blocking dielectric layer may be formed using a material having a high dielectric constant to provide a thin equivalent oxide thickness (EOT). The blocking dielectric layer may have a high density. Accordingly, a leakage current may be prevented from occurring through the blocking dielectric layer.

In this embodiment, processes substantially the same as those illustrated with reference to FIGS. 1 and 2 may be performed to the aluminum oxide layer 110 serving as the blocking dielectric layer. The aluminum oxide layer 110 formed by the processes may be low in hydrogen content to provide excellent trapping, current leakage and bad gap properties. The aluminum oxide layer 110 having a high density may have a close-packed structure.

After forming the aluminum oxide layer 110, the aluminum oxide layer 110 may be thermally treated to cure crystal defects in the aluminum oxide layer 110. The thermal treatment process may be performed under a temperature of about 700° C. to 1000° C. The thermal treatment process may include an ultraviolet ozone (UV-O₃) process or a plasma process.

Although it is not illustrated in the figure, a butting process may be further performed to remove the aluminum oxide layer 110 in a region for a selection transistor to be formed. Accordingly, following processes may be formed on the region where the aluminum oxide layer 110 removed, to form a MOS transistor for selecting a sell string.

Referring to FIG. 7, a metal layer 112 may be formed on the aluminum oxide layer 110. The metal layer 112 may include titanium, titanium nitride, tantalum, tantalum nitride, etc. These may be used alone or in a combination thereof. The metal layer 112 may be formed to a thickness of less than about 1000 Å. A polysilicon layer 114 doped with impurities may be formed on the metal layer 112. The metal layer 112 and the polysilicon layer 114 may be formed as a control gate pattern by following processes.

Referring to FIG. 8, a hard mask pattern 116 may be formed on the polysilicon layer 114. The polysilicon layer 114, the metal layer 112, the aluminum oxide layer 110 and the preliminary floating gate pattern 104 may be sequentially etched to form a gate structure. The gate structure may include the tunnel oxide layer 102, a floating gate pattern 104a having an isolated shape, a dielectric layer pattern 110a having an aluminum oxide on the floating gate pattern 104a, a control gate pattern 115 having a linear shape and the hard mask pattern 116. The control gate pattern 115 may include a stacked structure of metal and polysilicon.

Impurities may be implanted into a surface of the substrate 100 in both sides of the gate structure to form an impurity region 118.

The above-processes may be performed to form a flash memory device including an aluminum oxide having a high dielectric constant, a high density and low impurity content.

### EMBODIMENT 2

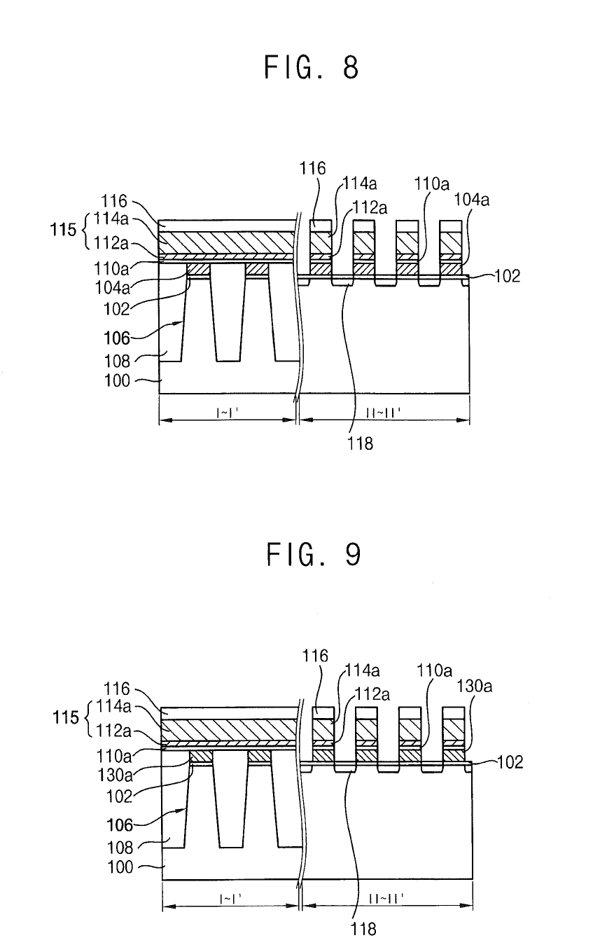

FIG. 9 is a cross-sectional view illustrating a flash memory device in accordance with a second example embodiment. The flash memory device of this embodiment includes the aluminum oxide layer that is illustrated with reference to FIGS. 1 and 2. The flash memory device of this embodiment is substantially the same as in Embodiment 1 except that a charge trapping layer is used for trapping electric charges.

Referring to FIG. 9, a substrate 100 having an isolation layer pattern (not illustrated) may be provided. A tunnel oxide layer 102, a charge trapping layer pattern 130a and a dielectric layer pattern 110a may be provided on the substrate 100.

The charge trapping layer pattern 130a may include silicon nitride. Alternatively, the charge trapping layer pattern 130a may include metal oxide.

The dielectric layer pattern 110a may include aluminum oxide. The aluminum oxide may be formed by the method illustrated with reference to FIGS. 1 and 2. Accordingly, the aluminum oxide may have a high density and low impurity content, and thus, may have an excellent trapping property

A control gate pattern 115 may be provided on the dielectric layer pattern 110a. The control gate pattern 115 may have a stacked structure of a metal layer pattern 112a and a polysilicon layer pattern 114a. A hard mask pattern 116 may be provided on the control gate pattern 115. An impurity region 118 may be provided under a surface of the substrate 100 in both sides of a gate structure including the tunnel oxide layer 102, the charge trapping layer pattern 130a, the dielectric layer pattern 110a, the control gate pattern 115 and the hard mask pattern 116.

The nonvolatile memory device of this embodiment may be formed by the processes substantially the same as those illustrated with reference to FIGS. 5 to 8, except that a charge trapping layer is formed to be used for trapping electric charges instead of a floating gate layer.

### EMBODIMENT 3

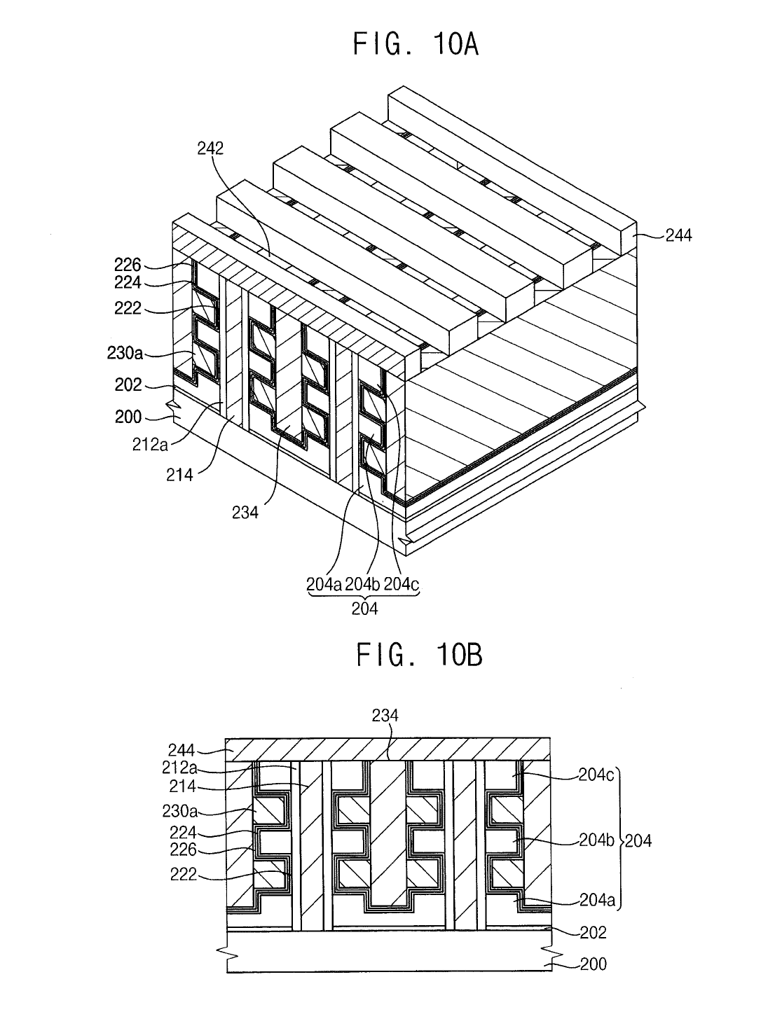

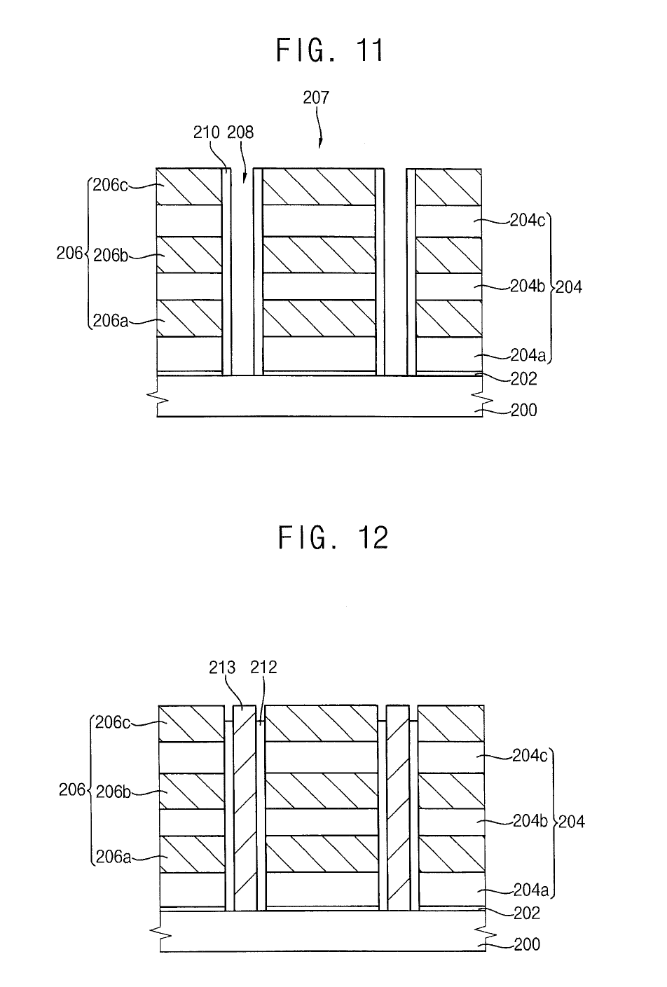

FIG. 10A is a perspective view illustrating a vertical-type NAND flash memory device in accordance with a third example embodiment. FIG. 10B is a cross-sectional view illustrating the vertical-type NAND flash memory device of FIG. 10A.

The vertical-type NAND flash memory device of this embodiment includes the aluminum oxide layer that is illustrated with reference to FIGS. 1 and 2.

Referring to FIGS. 10A and 10B, a substrate 200 including a single-crystalline semiconductor material may be provided. An impurity region (not illustrated) may be provided under a surface of the substrate 200 to be provided as a common source line. The impurity region may be connected to a lower portion of each of cell strings that is formed in a single-crystalline semiconductor pattern 212a.

A pad oxide layer 202 may be provided on the substrate 200. Insulation layer patterns 214 may be provided on the substrate 200. The insulation layer pattern 214 may have a linear shape extending in a first direction. The insulation layer pattern 214 may be arranged vertically to the surface of the substrate 200.

Pillar-shaped single-crystalline semiconductor patterns 212a may be provided on both sidewalls of the insulation layer pattern 214. A plurality of the single-crystalline semiconductor patterns 212a are repeatedly arranged on both the sidewalls of one insulation layer pattern 214. The single-crystalline semiconductor patterns 212a may have a sidewall inclination angle that is substantially perpendicular to the substrate 100. The single-crystalline semiconductor pattern 212a may have a rectangular parallelepiped shape.

Cell transistors may be provided on a sidewall of the single-crystalline semiconductor pattern 212a opposite to the other sidewall thereof facing the insulation layer pattern 214. Hereinafter, the other sidewall of the single-crystalline semiconductor pattern 212a facing the insulation layer pattern 214 is referred to as a first sidewall, and the sidewall opposite to the first sidewall, in which the cell transistors are formed, is referred to as a second sidewall. The cell transistors that are respectively formed in the single-crystalline semiconductor patterns 212a having the pillar shape constitutes one cell string. The cell transistors of a common cell string are connected to one another along the single-crystalline semiconductor patterns in a vertical direction.

Insulation interlayer patterns 204 may be provided on the second sidewall of the single-crystalline semiconductor pattern 212a to make contact with the second sidewall thereof. The insulation interlayer patterns 204 may be spaced apart from one another by a predetermined distance. The insulation interlayer pattern 204 may have a linear shape.

The cell transistor may be provided in a gap between the insulation interlayer patterns 204. Next, the cell transistor formed on the single-crystalline semiconductor pattern 212a will be further explained in detail.

A tunnel oxide layer 222 may be provided on a sidewall of the single-crystalline semiconductor pattern 212a. Charge trapping layers 224 may be provided on the tunnel oxide layer 222. The charge trapping layer 224 may include silicon nitride that is capable of trapping electric charge.

A blocking dielectric layers 226 may be provided on the charge-trapping layer 224. The blocking dielectric layer 226 may include aluminum oxide. The aluminum oxide may be formed by the method illustrated with reference to FIGS. 1 and 2. Accordingly, the aluminum oxide may have a high density due to the reduced oxide vacancies and may have an excellent trapping property due to the low impurity content. Thus, the vertical-type NAND flash memory device may include the blocking dielectric layer having a high density and low impurity content, to thereby decrease a current leakage and improve reliability thereof.

Like the charge trapping layer 224, the blocking dielectric layer 226 in the same layer are connected to one another laterally in the first direction. As illustrated in the figures, the blocking dielectric layers 226 formed on the same single-crystalline semiconductor pattern 212a may be connected to one another in the vertical direction.

Control gate patterns 230a may be provided in the gap between the insulation interlayer patterns on the surface of the blocking dielectric layer 226. The control gate patterns 230a in the same layer arranged in the first direction may have a linear shape. Accordingly, the control gate pattern 230a may be provided as a word line.

A silicon oxide layer pattern 242 may be provided between the insulation interlayer patterns 204 and the control gate patterns 230a.

A bit line 244 may be provided on the upper surfaces of the single-crystalline semiconductor patterns 212a to electrically connect the single-crystalline semiconductor patterns 212a.

Although not illustrated in the figures, in this embodiment, upper and lower selection transistors including a gate insulation layer pattern and a gate electrode may be provided on each of the uppermost and lowermost sidewalls of the single-crystalline semiconductor pattern 212a.

In this embodiment, the vertical-type NAND flash memory device may include the blocking dielectric layer of aluminum oxide having a high density and low impurity content, to thereby provide improved electrical characteristics.

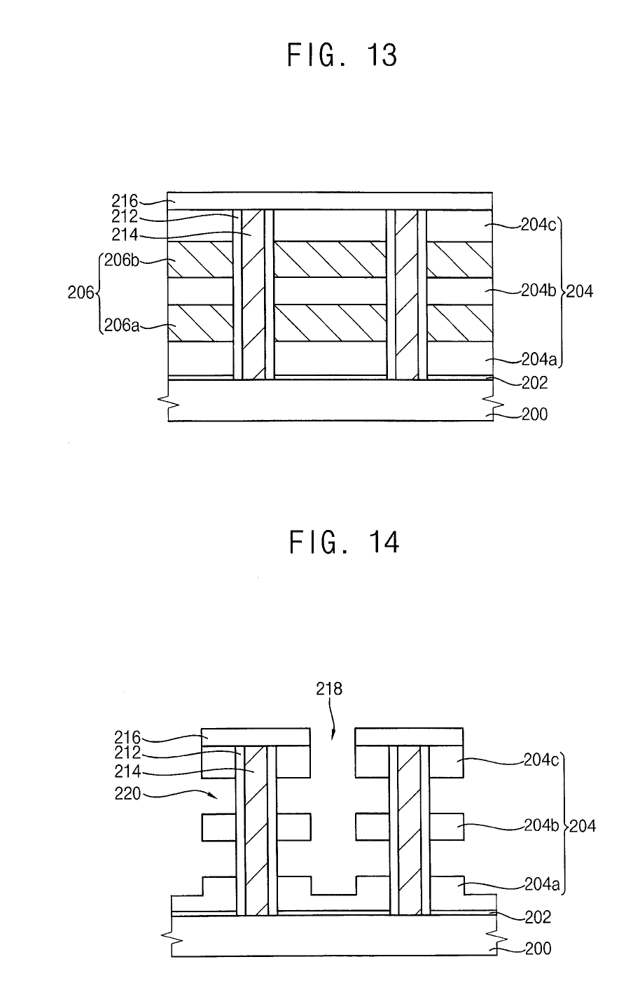

FIGS. 11 to 19 are cross-sectional views illustrating a method of manufacturing the vertical-type NAND flash memory device in FIGS. 10A and 10B. FIG. 17 is a partially enlarged view of a portion of FIG. 16.

Referring to FIG. 11, a substrate 200 including single-crystalline silicon may be prepared. N-type impurities may be partially implanted into a portion of the substrate to form impurity regions (not illustrated). The impurity region may be provided as a common source line of a NAND flash memory device. A pad oxide layer 202 may be formed on the substrate 200. An insulation interlayer and a sacrificial layer may be repeatedly formed on the pad oxide layer 202.

A first etching mask pattern (not illustrated) may be formed on the uppermost sacrificial layer. The sacrificial layers and the insulation interlayers may be sequentially etched using the first etching mask pattern to form an insulation layer structure having first trenches 208 extending in a first direction. Accordingly, the insulation layer structure may have a stacked structure of sacrificial layer patterns 206 and insulation interlayer patterns 204.

An amorphous silicon layer (not illustrated) may be formed on the sidewalls of the first trenches 208, the surface of the substrate 200 and upper surfaces of the insulation layer structure. The amorphous silicon layer may be anisotropically etched such that the amorphous silicon layer remains only on both the sidewalls of the first trench 208, to form an amorphous silicon pattern 110 having a spacer shape.

Referring to FIG. 12, a silicon oxide layer pattern 213 may be formed to fill the first trench 108 having the amorphous silicon pattern 210 formed therein.

Then, a thermal treatment process or a laser beam irradiation process may be performed such that the amorphous silicon pattern 210 may undergo a phase transition to form a preliminary single-crystalline silicon pattern 212. Accordingly, amorphous silicon may be thermally treated to undergo phase transition to single-crystalline silicon.

Referring to FIG. 13, portions of the silicon oxide layer pattern 213 and the preliminary single-crystalline silicon pattern 212, and the uppermost sacrificial layer 206c may be planarized until an upper surface of the uppermost insulation interlayer 204c is exposed, to form an insulation layer pattern 214 filling the first trench 208. By performing the planarization process, the preliminary single-crystalline silicon pattern 212 may have an evened upper surface.

Then, a capping layer 216 may be formed on the uppermost insulation interlayer pattern 204c, the insulation layer pattern 214 and the preliminary single-crystalline silicon pattern 212.

Referring to FIG. 14, a second etching mask pattern (not illustrated) may be formed on the capping layer 216 to expose a portion of the insulation layer structure between preliminary single-crystalline silicon patterns 212. Then, the capping layer 216 and each of the layers of the insulation layer structure may be sequentially etched using the second etching mask pattern to form a first opening 218.

Each of the remaining portions of the sacrificial layers 206 that is exposed through sidewalls of the first opening 218 may be removed by a wet etching process, to form a second opening 220 connected to a side of the first opening 218. The sidewalls of the preliminary single-crystalline silicon pattern 212 may be partially exposed through the second opening 220.

By performing the etching process, insulation interlayer patterns 204 may be formed on portions of the sidewalls of the preliminary single-crystalline silicon pattern 212 to extend in the first direction. The second opening 220 may be formed between the insulation interlayer patterns 204.

Referring to FIG. 15, a tunnel oxide layer 222 may be formed on the exposed portion of the preliminary single-crystalline silicon pattern 212. The tunnel oxide layer 222 may be formed by a thermal oxidation process or a CVD process. A charge trapping layer 224 may be formed on a surface of the tunnel oxide layer 222. The charge-trapping layer 224 may be formed by a CVD process. The charge trapping layer 224 may be formed using silicon nitride or metal oxide. Because silicon nitride and metal oxide are an insulating material, even though the material is conformally formed on the surfaces of the tunnel oxide layer 222, each of cell transistors may not be electrically connected to one another.

Referring to FIGS. 16 and 17, a blocking dielectric layer 226 may be formed on a surface of the charge trapping layer 224. The blocking dielectric layer 226 may be formed using aluminum oxide. The aluminum oxide may be formed by the method illustrated with reference to FIGS. 1 and 2. Accordingly, the blocking dielectric layer may have a high density due to the reduced oxide vacancies and may have an excellent trapping property due to the low impurity content.

Referring to FIG. 18, a conductive layer (not illustrated) may be formed on the blocking dielectric layer 226 to completely fill the first opening 218 and the second opening 212. After the deposition of the conductive layer, the conductive layer may be planarized until the upper surface of the uppermost insulation interlayer 204c is exposed, to form a conductive layer pattern (not illustrated) in the first and second openings 218 and 220.

A third etching mask pattern (not illustrated) may be formed on an upper surface of the resultant structure to selectively expose a portion of the conductive layer pattern formed in the first opening 218. The exposed conductive layer pattern may be anisotropically etched using the third etching pattern to form a third opening 232 that separates the conductive layer patterns in each of the layers apart from one another in the vertical direction. The third opening 232 may have the same shape as the first opening 218.

By the above-mentioned process, control gate patterns 230a may be formed between each of the layers of the insulation interlayer patterns 204. An upper surface, a lower surface and a sidewall of the control gate pattern 230a face the blocking dielectric layer pattern 226.

Referring to FIG. 19, a silicon oxide layer may be deposited in the third opening 232 and then the silicon oxide layer may be planarized until the uppermost insulation interlayer 204c is exposed, to form a first silicon oxide layer pattern 234.

Then, as illustrated in FIGS. 10A and 10B, a portion of the preliminary single-crystalline silicon pattern 212 may be anisotropically etched to form a single-crystalline semiconductor pattern 212a having a pillar shape. A second silicon oxide layer pattern 242 may be formed in a gap between the single-crystalline semiconductor patterns 212.

A bit line may be formed to electrically connect upper surfaces of the single-crystalline semiconductor patterns 212a that arranged in the first direction.

By the above-mentioned processes, a vertical-type NAND flash memory device may be formed on the substrate.

### EMBODIMENT 4

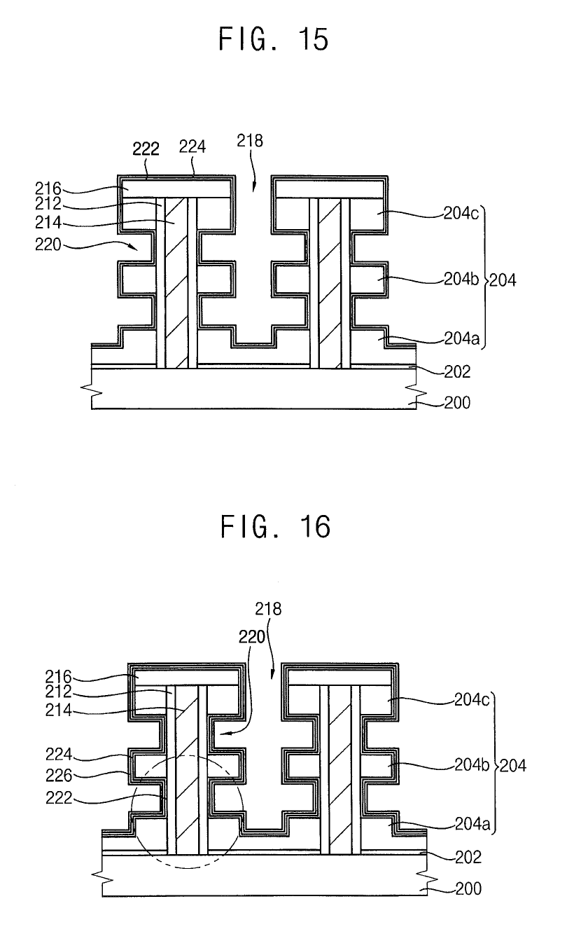

FIG. 20 is a cross-sectional view illustrating a capacitor in accordance with a fourth example embodiment.

Referring to FIG. 20, a lower electrode 252 may be provided on a substrate 250. The lower electrode 252 may include polysilicon, titanium, titanium nitride, tantalum, tantalum nitride, tungsten nitride, ruthenium, etc. These may be used alone or in a combination thereof.

A dielectric layer pattern 254 may be provided on the lower electrode 252. The dielectric layer pattern 254 may include aluminum oxide. The aluminum oxide may be formed by the method illustrated with reference to FIGS. 1 and 2. Accordingly, the dielectric layer pattern 254 including the aluminum oxide may have a high dielectric constant. The dielectric layer pattern 254 may have a high density and may have low impurity content. Thus, the capacitor including the dielectric layer pattern may have a high capacitance without a current leakage.

An upper electrode 259 may be provided on the dielectric layer pattern 254. In particular, a metal pattern 256 may be provided on the dielectric layer pattern 254. A polysilicon pattern 258 may be provided on the metal pattern 256. The metal pattern 256 may included titanium nitride, tungsten nitride, ruthenium, etc.

In this embodiment, the lower electrode of the capacitor may have a stacked structure. Alternatively, the lower electrode may have a cylindrical shape.

Hereinafter, a method of manufacturing the capacitor of FIG. 20 will be explained in detail.

First, a lower electrode layer may be formed on the substrate 250. The lower electrode layer may be formed using a conductive material. Examples of the conductive material may be polysilicon, titanium, titanium nitride, tantalum, tantalum nitride, tungsten nitride, ruthenium, etc. These may be used alone or in a combination thereof.

A dielectric layer may be formed on the lower electrode layer. The dielectric layer may be formed by the method illustrated with reference to FIGS. 1 and 2. After forming the dielectric layer, the dielectric layer may be thermally treated to cure crystal defects in the dielectric layer.

An upper electrode layer may be formed on the dielectric layer. The upper electrode layer may be formed using a conductive material. For example, the upper electrode layer may have a stacked structure of metal and polysilicon. Alternatively, the upper electrode layer may be formed using metal or metal nitride. The upper electrode layer may include titanium, titanium nitride, tantalum, tantalum nitride, tungsten nitride, etc. A lower portion of the upper electrode layer contacting a surface of the dielectric layer may be formed using a metal material.

Then, the upper electrode layer, the dielectric layer and the lower electrode layer may be patterned to form a capacitor. The capacitor may include the lower electrode 252, the dielectric layer pattern 254 and the upper electrode 259. Since the capacitor includes the dielectric layer pattern of the aluminum oxide, the capacitor may have a high capacitance.

### EMBODIMENT 5

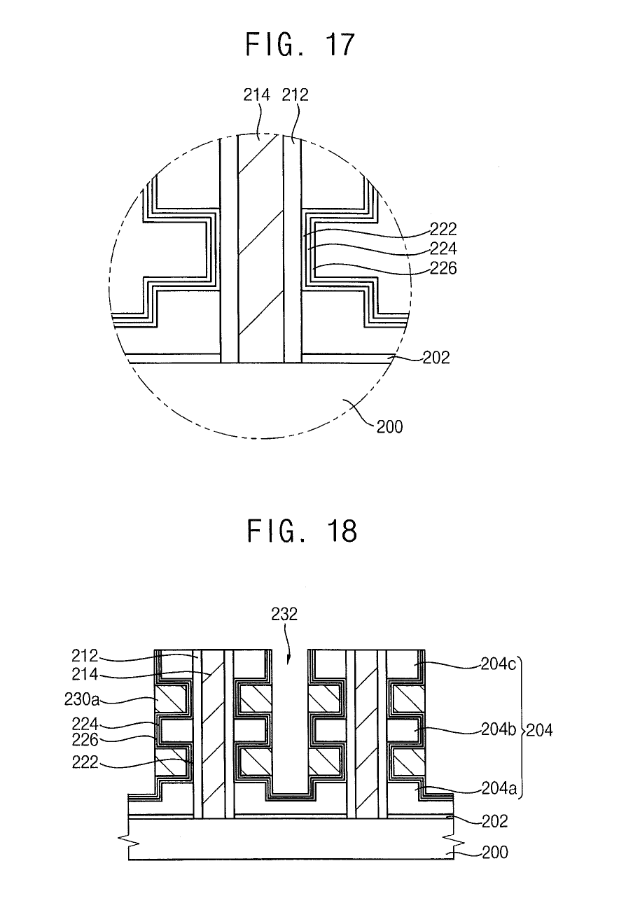

FIG. 21 is a cross-sectional view illustrating a DRAM device in accordance with a fifth example embodiment.

Referring to FIG. 21, an isolation layer pattern 304 may be provided in a substrate 300 to define an active region and an isolation region in the substrate 300. The active region may have an isolated shape.

A selection transistor may be provided on the substrate 300. The selection transistor may include a gate structure of a gate dielectric layer 306, a gate electrode 308 and a hard mask pattern 310. Impurity regions 314 may be provided in both sides of the gate structure.

For example, the gate dielectric layer 306 may include a metal oxide. The gate electrode 308 may include a stacked structure of metal and polysilicon. The metal oxide may be aluminum oxide. The aluminum oxide may be formed by the method illustrated with reference to FIGS. 1 and 2. Alternatively, the gate electrode 308 may include polysilicon.

A bit line 32 may be provided to be electrically connected to one of the impurity regions 314. The impurity region 314 may be electrically connected to the bit line 32 by a first pad contact 318a and a bit line contact.

A capacitor may be provided to be electrically connected to another of the impurity regions 314. The impurity region 314 may be electrically connected to the capacitor by a second pad contact 318b and a storage node contact 326.

The capacitor may include a cylindrical-shaped lower electrode 328, a dielectric layer 330 of aluminum oxide and an upper electrode 332.

The lower electrode 328 may include polysilicon, titanium, titanium nitride, tantalum, tantalum nitride, tungsten nitride, ruthenium, etc. These may be used alone or in a combination thereof.

The upper electrode 332 may include titanium, titanium nitride, tantalum, tantalum nitride, tungsten nitride, ruthenium, etc. These may be used alone or in a combination thereof. The upper electrode 332 may further include a polysilicon electrode in an upper portion.

The dielectric layer 330 of the capacitor may include aluminum oxide that is formed by the method illustrated with reference to FIGS. 1 and 2.

Hereinafter, a method of manufacturing the DRAM device of FIG. 21 will be explained in detail.

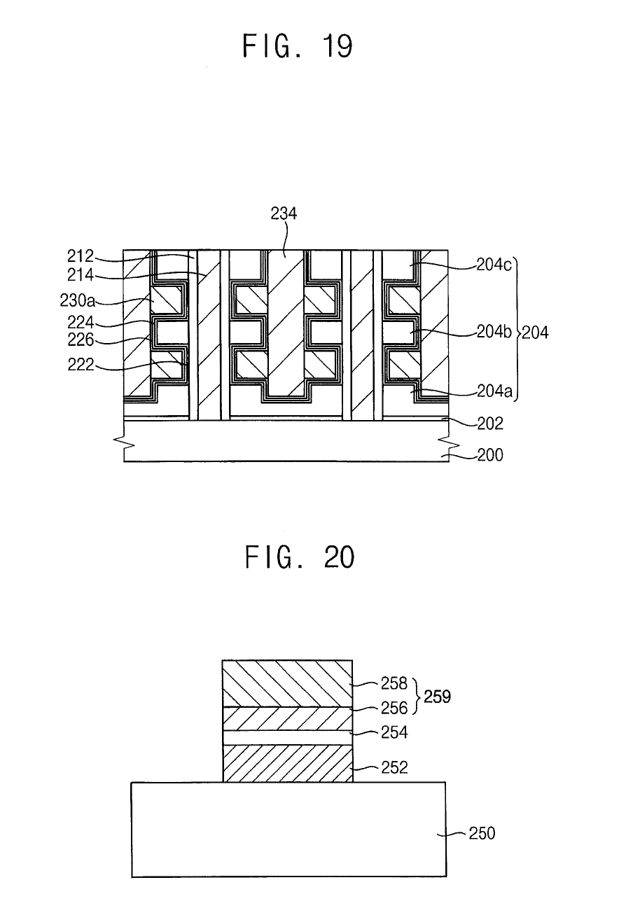

FIGS. 22 to 24 are cross-sectional views illustrating a method of manufacturing a DRAM device.

Referring to FIG. 22, a pad oxide layer pattern and a first hard mask pattern may be formed on a substrate 300. The substrate 300 may be etched using the first hard mask pattern as an etching mask to form an isolation trench 302. An insulation layer may be formed to fill the trench 302, and then, may be planarized to form an isolation pattern 304. Accordingly, an active region and an isolation region may be defined in the substrate 300.

A gate dielectric layer 306 may be formed on the substrate 300. The gate dielectric layer 306 may be formed using a metal oxide. For example, the gate dielectric layer may include aluminum oxide that is formed by the method illustrated with reference to FIGS. 1 and 2. Alternatively, the gate dielectric layer 306 may be formed using silicon oxide.

A gate electrode layer (not illustrated) and a hard mask pattern 310 may be formed on the gate dielectric layer 306. The gate electrode layer may be etched using the hard mask pattern 310 to form a gate electrode 308. A spacer 312 may be formed on sidewalls of the gate electrode 308. Impurities may be implanted into the substrate in both sides of the gate electrode 308. Thus, selection transistors may be formed on the substrate 300.

A first insulation interlayer 316 may be formed on the substrate 300 to cover the selection transistor. The firs insulation interlayer 316 may be partially etched to form first contact holes that expose the impurity regions 314. A conductive material may be formed in the first contact holes to form first and second pad contacts 318a and 318b that are electrically connected to the impurity regions 314.

A second insulation interlayer 320 may be formed on the first insulation interlayer 316. The second insulation interlayer 320 may be partially etched to form second contact holes (not illustrated) that expose upper surfaces of the first pad contacts 318a. A conductive material may be formed in the second contact holes to form bit line contacts. A bit line 322 may be formed on the second insulation interlayer 320 to contact the bit lines contacts.

A third insulation interlayer 324 may be formed on the second insulation interlayer 320 to cover the bit line 322.

The third and second insulation interlayers 324 and 320 may be partially etched to form third contact holes that expose the second contact pads 318b. A conductive material may be formed in the third contact holes to form storage node contacts 326.

Referring to FIG. 23, a mold layer (not illustrated) may be formed on the third insulation interlayer 324. The mold layer may be partially etched to form an opening (not illustrated) that exposes an upper surface of the storage node contact 326.

A lower electrode conductive layer (not illustrated) may be formed on sidewalls and a lower surface of the opening and an upper surface of the mold layer. The lower electrode conductive layer may include polysilicon, titanium, titanium nitride, tantalum, tantalum nitride, tungsten nitride, ruthenium, etc. These may be used alone or in a combination thereof.

After a sacrificial layer (not illustrated) is formed on the lower electrode conductive layer, the sacrificial layer and the lower electrode conductive layer may be partially removed until the upper surface of the mold layer is exposed. Thus, the lower electrode conductive layer may be patterned to form a cylindrical-shaped lower electrode 328. Then, the sacrificial layer and the mold layer may be removed from the substrate.

Referring to FIG. 24, a dielectric layer 330 may be formed on the lower electrode 328. The dielectric layer 330 may be formed using aluminum oxide. The aluminum oxide may be formed by the method illustrated with reference to FIGS. 1 and 2. Accordingly, the dielectric layer may have a thin equivalent oxide thickness and a high dielectric constant. The dielectric layer may prevent a current leakage between the lower electrode 328 and the upper electrode 332.

After forming the dielectric layer 330, the dielectric layer 330 may be thermally treated to cure oxygen deficiency in the dielectric 330. The thermal treatment process may include an ultraviolet ozone (UV-O₃) process or a plasma process.

As illustrated in FIG. 21, the upper electrode 332 may be formed on the dielectric layer 330. The upper electrode conductive layer may include titanium nitride, tantalum nitride, tungsten nitride, ruthenium, etc. These may be used alone or in a combination thereof.

Accordingly, a capacitor including the cylindrical-shaped lower electrode 328, the dielectric layer 330 of aluminum oxide and the upper electrode 332.

Since the dielectric layer 330 of the capacitor includes the aluminum oxide having a high dielectric constant, a high density and an excellent trapping property, the capacitor may have improved characteristics such as a high capacitance.

### EXPERIMENTS ON CHARACTERISTICS OF ALUMINUM OXIDE LAYERS

### Example

An aluminum oxide layer of Example was formed by the method illustrated with reference to FIGS. 1 and 2. Cycles including an ozone supply step, a first purge step, an aluminum source gas and dilution gas supply step and a second purge step were performed repeatedly to form the aluminum oxide layer on a substrate. A carrier gas was used to vaporize an aluminum source and carry the vaporized aluminum source gas. The substrate was heated to a temperature of about 550° C. during depositing the aluminum oxide layer. TMA was used as the aluminum source gas and a nitrogen gas was used as a dilution gas. The dilution gas and the aluminum source gas ware supplied at a flow rate ratio of 1:40.

### Comparative Example

An aluminum oxide layer of Comparative Example was formed by repeatedly performing cycles including an ozone supply step, a first purge step, an aluminum source gas supply step and a second purge step. The aluminum oxide layer of Comparative Example was formed to have a thickness substantially the same as that of Example. The carrier gas was substantially the same as that of Example. The substrate was heated to a temperature of about 380° C. during depositing the aluminum oxide layer. TMA was used as the aluminum source gas. A dilution gas was not used.

Densities of Aluminum Oxide Layers

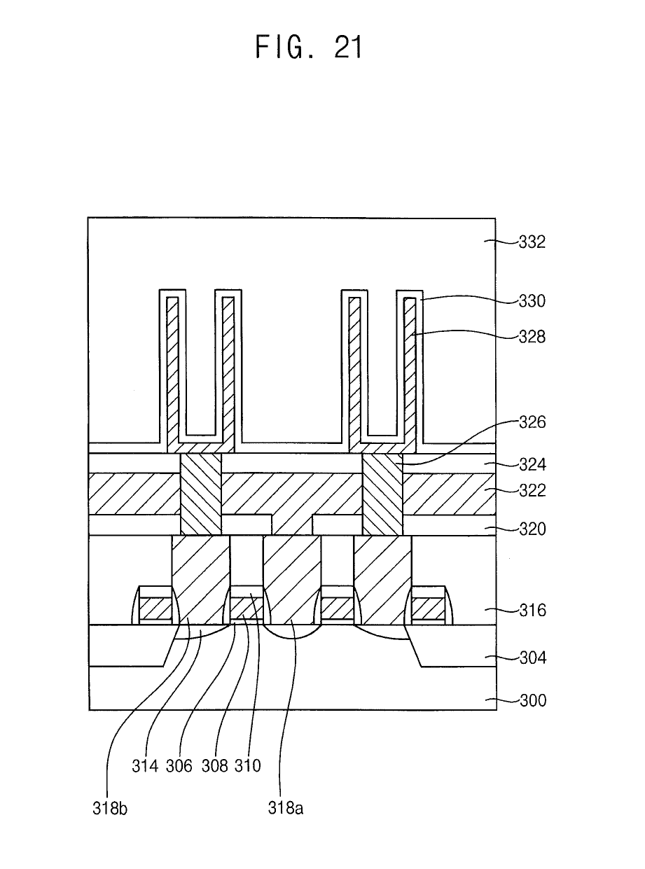

FIG. 25 illustrates a graph showing densities of aluminum oxide layers according to Example and Comparative Example.

Experiments were performed using X-ray Reflectivity with respect to the densities of the aluminum oxide layers according to Example and Comparative Example.

Referring to FIG. 25, the aluminum oxide layer 500 of Example had a higher density than the aluminum oxide layer 510 of Comparative Example.

Etching Rates of Aluminum Oxide Layers

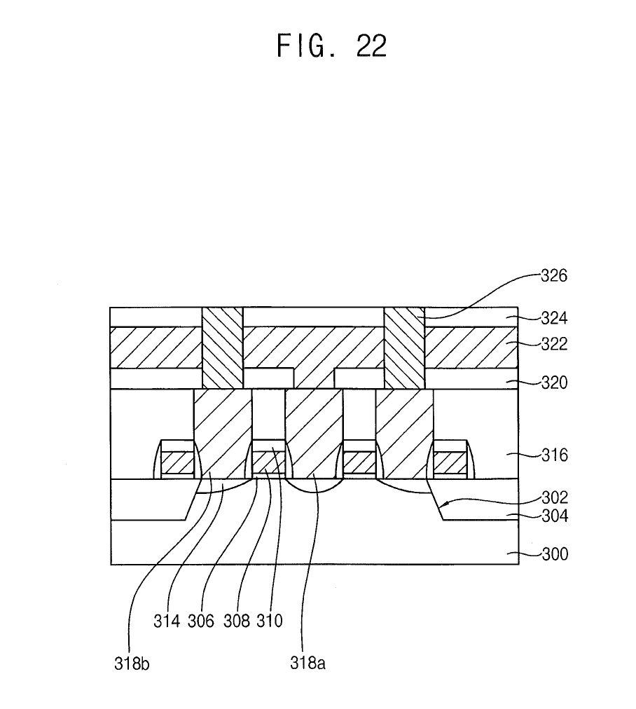

FIG. 26 illustrates a graph showing etched thicknesses of aluminum oxide layers versus an etching time according to Example and Comparative Example.

Experiments were performed using a wet etching process with respect to the etched thickness of the aluminum oxide layers according to Example and Comparative Example. The aluminum oxide layers of Example and Comparative Example were etched under the same conditions of the wet etching process. A HF dilution solution was used in the wet-etch process.

Referring to FIG. 26, the aluminum oxide layer 502 of Example had a lower etching rate than the aluminum oxide layer 512 of Comparative Example. Accordingly, the aluminum oxide layer 502 of Example may have a more close-packed structure than the aluminum oxide layer 512 of Comparative Example. Further, the aluminum oxide layer 502 of Example having a lower etching rate may be easily controlled to be etched with a predetermined thickness.

Shrinking Rates of Aluminum Oxide Layers

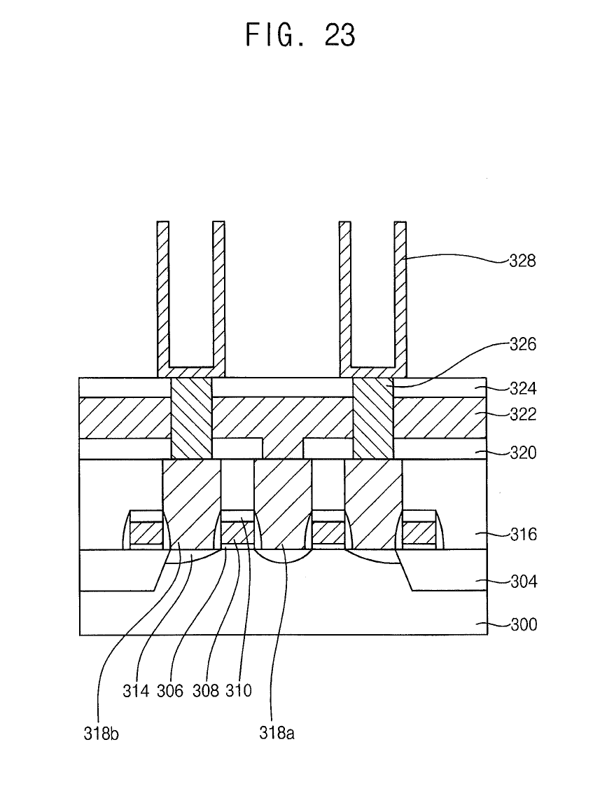

FIG. 27 illustrates a graph showing thicknesses of aluminum oxide layers before/after a crystallization process according to Example and Comparative Example.

Annealing processes were performed on the aluminum oxide layers according to Example and Comparative Example. The thicknesses of the aluminum oxide layers before/after the annealing process were measured. The annealing processes were performed under a temperature of about 1000° C.

The thickness of the aluminum oxide layer 504a, 504b of Example was decreased by about 10% after the annealing process for crystallization. The thickness of the aluminum oxide layer 514a, 514b of Comparative Example was decreased by about 13% after the annealing process for crystallization. Accordingly, the aluminum oxide layer of Example may have a more excellent shrinkage property than the aluminum oxide layer of Comparative Example. The aluminum oxide layer of Example may have a more close-packed structure than the aluminum oxide layer of Comparative Example

Current Leakages of Aluminum Oxide Layers

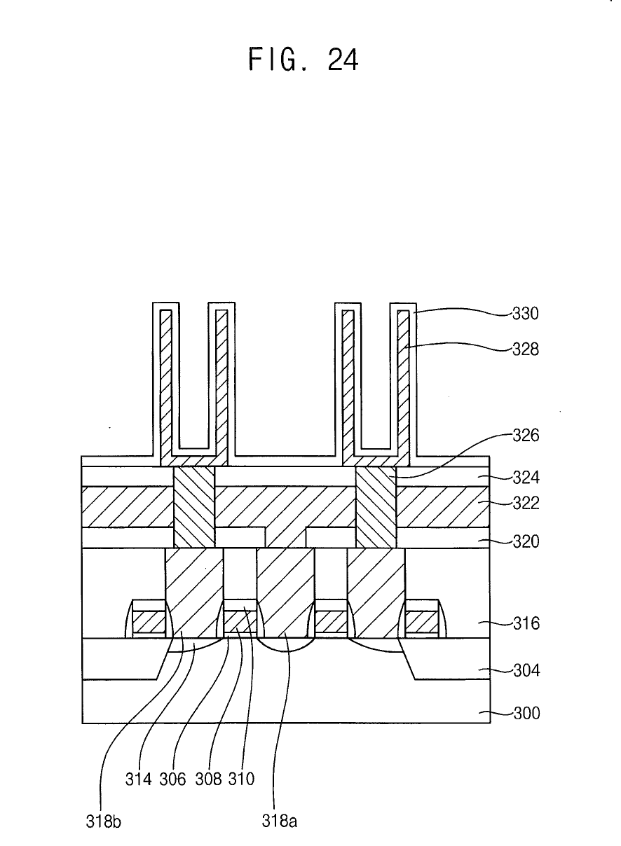

FIG. 28 illustrates a graph showing current densities of aluminum oxide layers versus an electric field according to Example and Comparative Example.

Experiments were performed using an electric field with respect to the current densities of the aluminum oxide layers according to Example and Comparative Example. The current densities of the aluminum oxide layers were measured as the electric field was applied to each of the aluminum oxide layers.

Referring to FIG. 28, the aluminum oxide layer 506 of Example had a lower current density than the aluminum oxide layer 516 of Comparative Example, under the same electric field. Accordingly, the aluminum oxide layer of Example may have a more excellent current leakage property than the aluminum oxide layer of Comparative Example.

Hydrogen Contents in Aluminum Oxide Layers

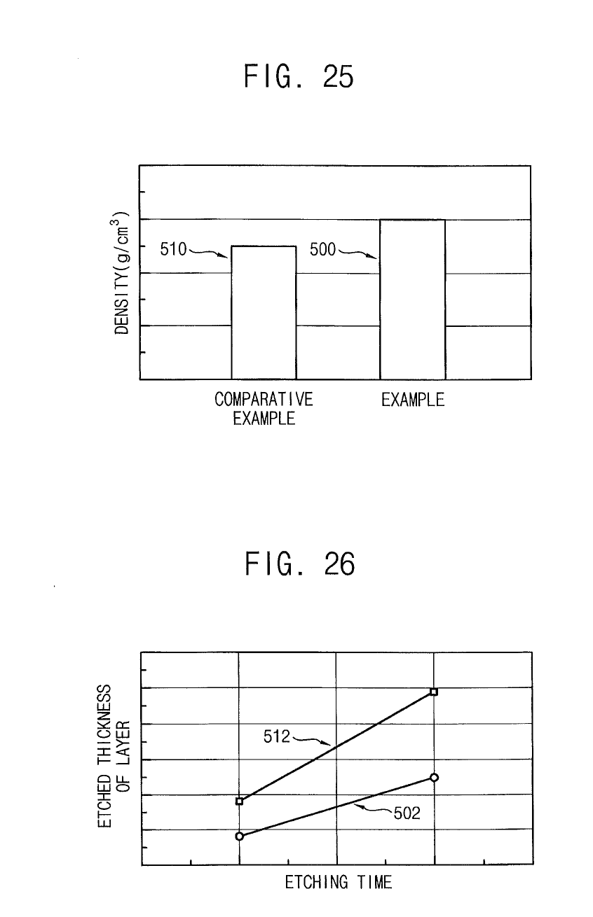

FIG. 29 illustrates a graph showing hydrogen contents in aluminum oxide layers according to Example and Comparative Example.

Experiments were performed using SIMS (secondary ion mass spectroscopy) with respect to the hydrogen contents included in the aluminum oxide layers according to Example and Comparative Example.

Referring to FIG. 29, the aluminum oxide layer 508 of Example had lower hydrogen content than the aluminum oxide layer 518 of Comparative Example. Accordingly, the aluminum oxide layer of Example may have relatively lower impurity content, to thereby improve trapping property.

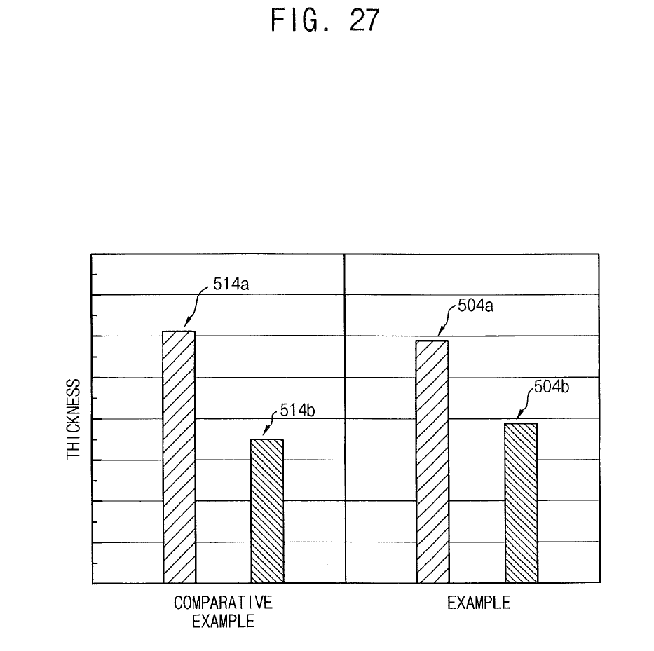

FIG. 30 illustrates another exemplary embodiment.

As illustrated in FIG. 30, this embodiment may be embodied as a memory card 630 including a memory 610 connected to a memory controller 620. The memory 610 may include the flash memory device and the DRAM device discussed above. The memory controller 620 supplies the input signals for controlling operation of the memory 610. For example, the memory controller 620 supplies the command CMD and address ADD signals, I/O signals, etc. It will be appreciated that the memory controller 620 may control the memory 610 based on received signals.

The memory card 630 may be a standard memory card to be coupled with an electronic device such as a digital camera, personal computer, etc. The memory controller 620 may control the memory 610 based on signals that received from an external device.

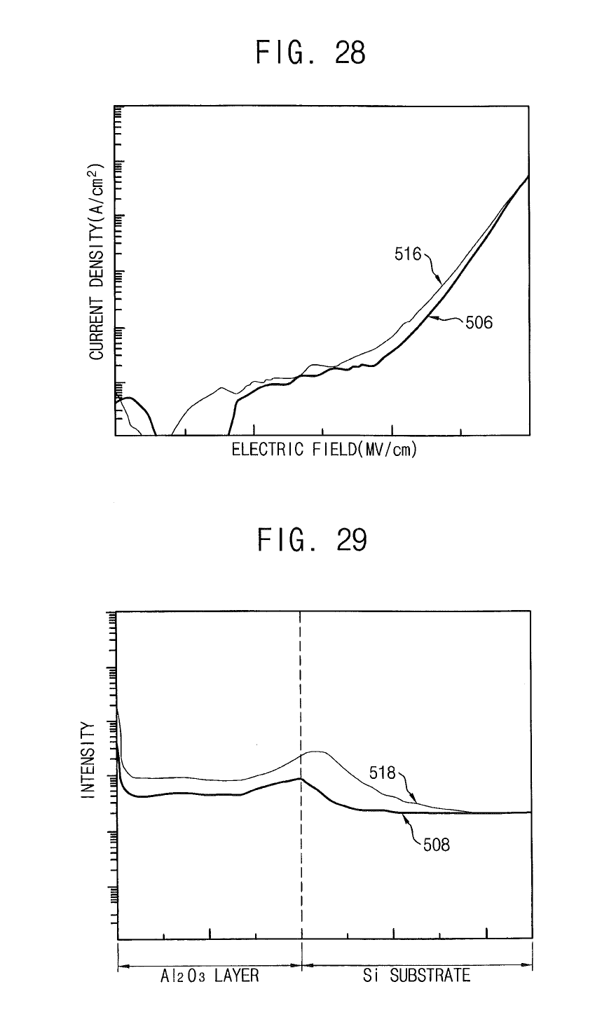

FIG. 31 illustrates yet another exemplary embodiment.

As illustrated, a portable device 700 may be an MP3 player, video player, combination video and audio player, etc. The portable device 700 includes the memory 610 and the memory controller 620. The memory 610 may include the flash memory device and the DRAM device discussed above. The portable device 700 may also includes an encoder/decoder EDC 710, a presentation component 720 and an interface 730. Data (video, audio, etc.) is input to and output from the memory 610 via the memory controller 620 by the EDC 610.

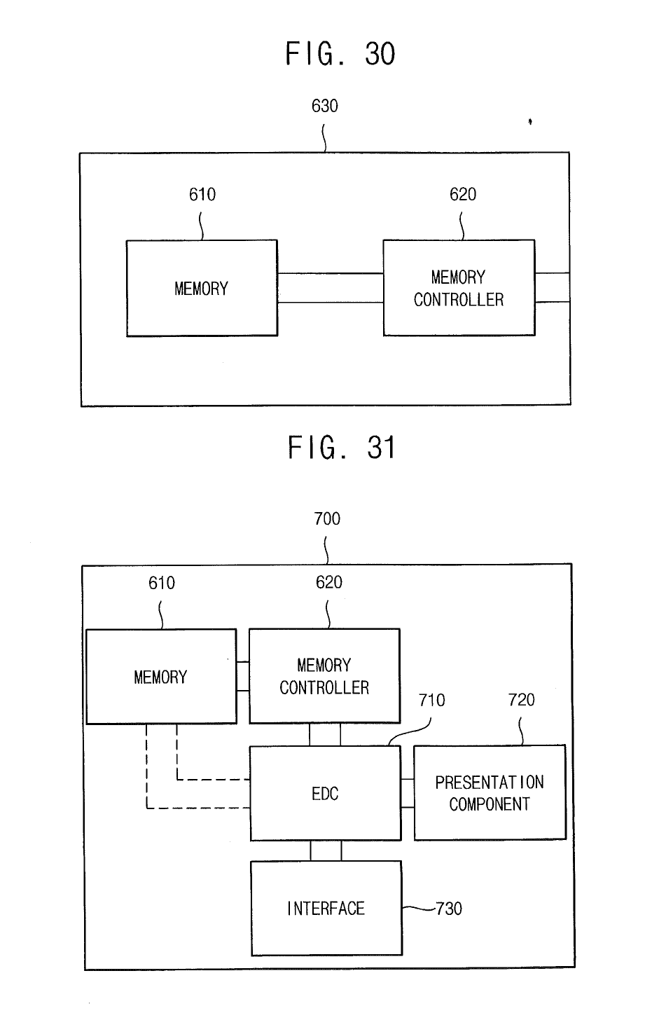

FIG. 32 illustrates a further exemplary embodiment.

As illustrated, the memory 610 may be connected to a central processing unit CPU 810 within a computer system 800. For example, the computer system 800 may be a personal computer, personal data assistant, etc. The memory 610 may be directly connected with the CPU 810, connected via BUS, etc.

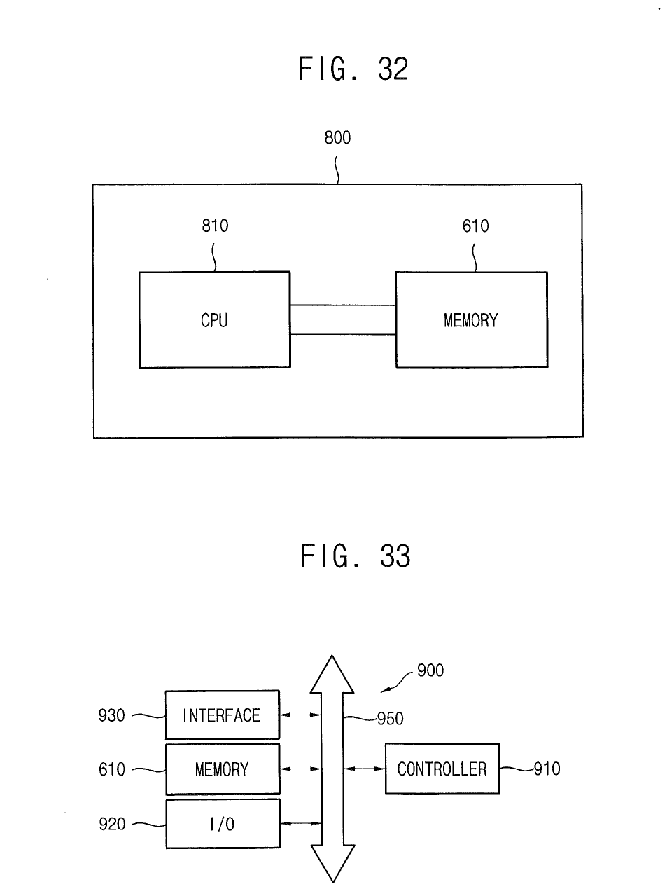

FIG. 33 illustrates a still further exemplary embodiment.

As illustrated, the device 900 may include a controller 910, an input/output device 920 such as a keyboard and a display, a memory 610 and an interface 930. The elements may communicate with one another via a bus 950. The controller may include al least one of a microprocessor, a digital processor, a microcontroller and a processor. The memory 610 may store data and/or command signals received from the controller 910. The interface 930 may be used to transmit data to/from another system such as a communication network. The device 900 may be a mobile system such as PDA, a portable computer, a Web tablet, a cordless phone, a mobile phone, a digital music player, a memory card or another system capable of transmitting and/or receiving information.

As mentioned above, an aluminum oxide layer according to example embodiments may be formed to have low impurity content and a high density, to thereby improve electrical properties of a semiconductor device including the aluminum oxide layer.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A method of forming an aluminum oxide layer, comprising:
i) supplying an aluminum source gas and a dilution gas into a chamber through a common gas supply nozzle so that the aluminum source gas is adsorbed on a substrate in the chamber;
ii) supplying a first purge gas into the chamber to purge the physically adsorbed aluminum source gas from the substrate;
iii) supplying an oxygen source gas into the chamber to form an aluminum oxide layer on the substrate;
iv) supplying a second purge gas into the chamber to purge a reaction residue and the physically adsorbed remaining gas from the substrate; and
v) performing i) to iv) repeatedly to form an aluminum oxide layer having a desired thickness.

2. The method of claim 1, wherein the substrate is heated to a temperature of about 450° C. to 700° C. in the chamber.

3. The method of claim 1, wherein the flow rate of the dilution gas is controlled such that the aluminum source gas is prevented from being decomposed in the gas supply nozzle.

4. The method of claim 3, wherein the flow rate ratio of the aluminum source gas and the dilution gas is in a range of about 1:5 to about 1:80.

5. The method of claim 1, wherein the aluminum source gas comprises at least one selected from the group consisting of trimethyl aluminium (Al(CH₃)₃), triethyl aluminium (Al(C₂H₆)₃), triisobutyl aluminium (Al[(C₂H₃(CH₃)₂]₃) and diethyl aluminium chloride (AlCl(C₂H₆)₃).

6. The method of claim 1, wherein the dilution gas comprises at least one selected from the group consisting of nitrogen, argon and helium.

7. The method of claim 1, wherein the oxygen source gas comprises ozone or vapor.

8. The method of claim 7, wherein the oxygen source gas comprises an ozone gas and the ozone gas is supplied with a concentration of about 350 g/cm³ and at a flow rate of about 10 slm.

9. The method of claim 8, wherein the ozone gas is generated from a plurality of ozone generators and the ozone gas is supplied into chamber through a common nozzle.

10. The method of claim 1, wherein the aluminum source gas and the dilution gas converge into a common gas supply tube from the respective gas supply tube such that the aluminum source gas is diluted with the dilution gas and the aluminum source gas diluted with the dilution gas is supplied into the chamber through the common gas supply nozzle.

11. The method of claim 1, further comprising thermally treating the aluminum oxide layer.

12. A method of manufacturing a flash memory device, comprising:
forming a tunnel oxide layer and a charge trapping layer pattern on a substrate;
loading the substrate including the charge trapping layer into a chamber;
supplying an aluminum source gas and a dilution gas into the chamber through a common gas supply nozzle so that the aluminum source gas is adsorbed on the substrate in the chamber;
supplying a first purge gas into the chamber to purge the physically adsorbed aluminum source gas from the substrate;
supplying an oxygen source gas into the chamber to form an aluminum oxide layer on the substrate;
supplying a second purge gas into the chamber to purge a reaction residue and the physically adsorbed remaining gas from the substrate; and
forming a control gate electrode on the aluminum oxide layer.

13. The method of claim 12, wherein the substrate is heated to a temperature of about 450° C. to 700° C. when the aluminum oxide layer is formed in the chamber.

14. The method of claim 12, the flow rate ratio of the aluminum source gas and the dilution gas is in a range of about 1:5 to about 1:80.

15. The method of claim 12, wherein the charge trapping layer comprises polysilicon or silicon nitride.

16. The method of claim 12, wherein the control gate electrode comprises a metal pattern that contacts the aluminum oxide layer.

17. A method of manufacturing a capacitor, comprising:
forming a lower electrode on a substrate;
loading the substrate including the lower electrode into a chamber;
supplying an aluminum source gas and a dilution gas into the chamber through a common gas supply nozzle so that the aluminum source gas is adsorbed on the substrate in the chamber;
supplying a first purge gas into the chamber to purge the physically adsorbed aluminum source gas from the substrate;
supplying an oxygen source gas into the chamber to form an aluminum oxide layer on the substrate;
supplying a second purge gas into the chamber to purge a reaction residue and the physically adsorbed remaining gas from the substrate; and
forming an upper electrode on the aluminum oxide layer.

18. The method of claim 17, wherein the substrate is heated to a temperature of about 450° C. to 700° C. when the aluminum oxide layer is formed in the chamber.

19. The method of claim 17, wherein the flow rate ratio of the aluminum source gas and the dilution gas is in a range of about 1:5 to about 1:80.

20. The method of claim 17, wherein the upper electrode comprises metal and polysilicon.
